(19) United States
(12) Patent Application Publication
(10) Pub. No.: US 2013/0120921 A1
(43) Pub. Date: May 16, 2013

(54) ENCLOSURE AND ELECTRONIC DEVICE USING SAME

(71) Applicant: JUI-KUN HSIEH, Tu-Cheng (TW)

(72) Inventor: JUI-KUN HSIEH, Tu-Cheng (TW)

(73) Assignee: HON HAI PRECISION INDUSTRY CO., LTD., Tu-Cheng (TW)

(21) Appl. No.: 13/455,280

(22) Filed: Apr. 25, 2012

(30) Foreign Application Priority Data
Nov. 11, 2011 (TW) 100141164

(51) Int. Cl. G06F 1/16; H05K 1/00; H05K 7/20; H01L 31/052; H05K 5/00

(52) U.S. Cl. 361/679.08; 136/246; 361/679.01; 361/714; 361/752; 361/749; 361/750

(57) ABSTRACT

An enclosure of an electronic device includes a number of thin film solar cells formed on the exterior, and a power module connected to the thin film solar cells. The thin film solar cells convert light impinging on the enclosure into electrical energy. The power module stores and distributes the electrical energy converted by the thin film solar cells to the electronic device.

### TECHNICAL FIELD

The disclosure generally relates to enclosures, and particularly, to an enclosure that can provide power to an electronic device.

### DESCRIPTION OF RELATED ART

Environmental concerns require that attention be paid to the environmental impact of a product. However, the design of the enclosure of many products is only focused on ornamental and weight considerations, and environmentally-conscious consumers may not be satisfied.

Therefore, it is desirable to provide an enclosure which can overcome the above-mentioned problems.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an electronic device in accordance with an exemplary embodiment of present disclosure, the electronic device including an enclosure.

FIG. 2 is a cross-sectional view of the surface of the enclosure of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

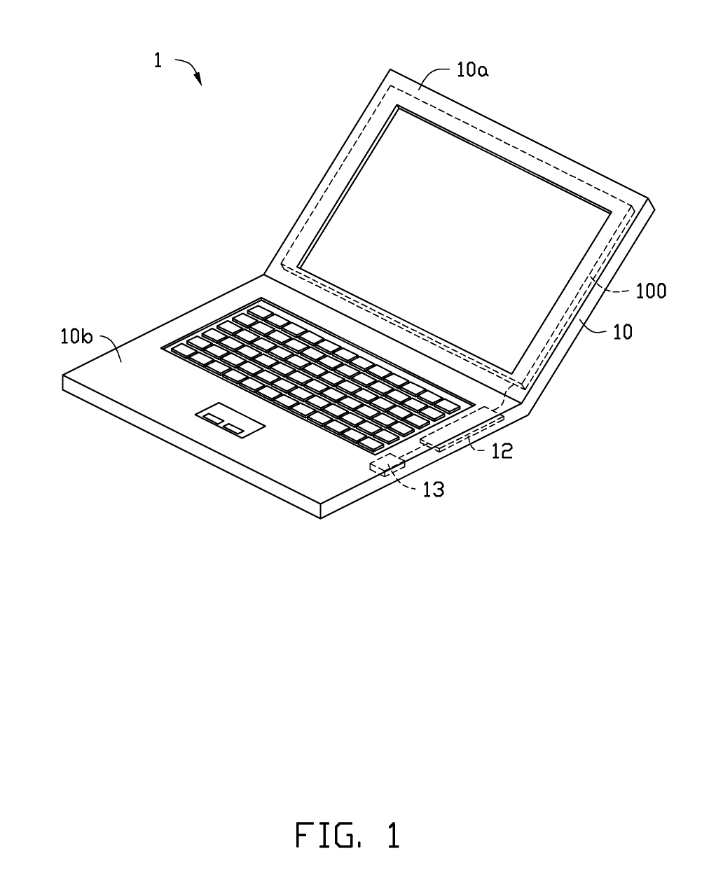

Referring to FIG. 1, an electronic device 1, in accordance with an exemplary embodiment of the present disclosure, is shown. The electronic device 1 includes an enclosure 10, a power module 12, a back up battery 13, and a number of thin film solar cells 100 formed on the enclosure 10. The thin film solar cells 100 convert light energy into electrical energy. The power module 12 is accommodated in the enclosure 10 and electrically connected to the thin film solar cells 100. The back up battery 13 is electrically connected to the power module 12. The power module 12 provides power to the electronic device 1 in the form of electrical energy outputted by the thin film solar cells 100. In this embodiment, the electronic device 1 is a notebook computer. The thin film solar cells 100 are formed on a display enclosure 10a of the notebook computer and a keyboard enclosure 10b of the notebook computer. When light shines on the thin film solar cells 100, the thin film solar cells 100 converts the light energy of the light into electrical energy and provides power to components of the notebook computer via the power module 12. The electrical energy converted by the thin film solar cells 100 can be directly provided to the components of the notebook computer, or can be stored in the back up battery 13.

In an alternative embodiment, the electronic device 1 is a portable smart terminal, such as a cellular phone or a music player.

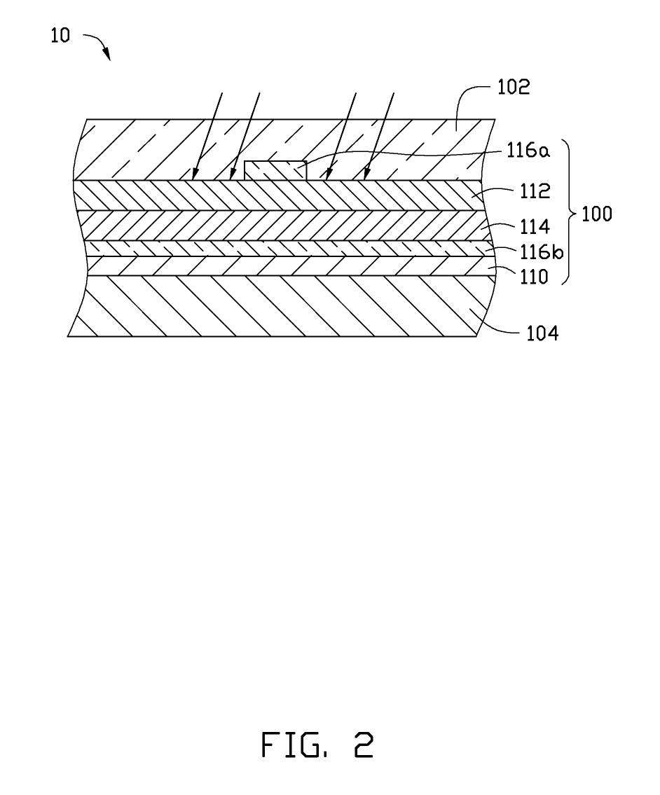

Referring to FIG. 2, the enclosure 10 includes a protection layer 102 and a heat dissipation layer 104. The thin film solar cells 100 are inserted between the protection layer 102 and the heat dissipation layer 104. The protection layer 102 is the outermost portion of the enclosure 100. The heat dissipation layer 104 is the innermost portion of the enclosure 100. The protection layer 102 covers the thin film solar cells 100 to protect the thin film solar cells 100 from external damage. The protection layer 102 is made of a lightweight transparent material with high strength. In this embodiment, the protection layer 102 is made of Polycarbonate.

Each of the thin film solar cells 100 includes a substrate 110, an n-type semiconductor layer 112 and a p-type semiconductor layer 114 formed above the substrate 110, an anode 116b formed on the p-type semiconductor layer 114, and a cathode 116a formed on the n-type semiconductor layer 112. The light passes through the protection layer 102 and strikes an interface between the n-type semiconductor layer 112 and the p-type semiconductor layer 114 to activate a number of electron-hole pairs. The electrons and holes are respectively collected at the n-type semiconductor layer 112 and at the p-type semiconductor layer 114, to generate a voltage. The voltage is applied to the power module 12 via the anode 116b and the cathode 116a. In this embodiment, the substrate 110 is made of flexible material. The n-type semiconductor layer 112 and the p-type semiconductor layer 114 are made of amorphous silicon. The thin film solar cells 100 are attached to the heat dissipation layer 104 via the substrate 110.

The thin film solar cells 100 are arranged between the heat dissipation layer 104 and the protection layer 102. The heat dissipation layer 104 dissipates any heat generated by the thin film solar cells 100, to keep the electronic device 1 at an acceptable temperature. The heat dissipation layer 104 is made of a lightweight material with high thermal conductivity. In this embodiment, the heat dissipation layer 104 is made of metal alloy or graphite. The thin film solar cells 100 are adhesively attached to the heat dissipation layer 104. In an alternative embodiment, the n-type semiconductor layer 112 and the p-type semiconductor layer 114 can be directly formed on the heat dissipation layer 104, and the substrate 110 of the thin film solar cells 100 can be omitted.

The power module 12 connects with the anode 116b and the cathode 116a to store and distribute the electrical energy converted by the thin film solar cells 100 to components of the electronic device 1. The power module 12 also can also be connected with an external power source or the back up battery 13 for providing uninterruptible power to the electronic device 1.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An apparatus, comprising:
a number of thin film solar cells; and
an enclosure comprising a transparent protection layer and a heat dissipation layer;
wherein the thin film solar cells are integrally formed with the enclosure, the thin film solar cells are formed between the protection layer and the heat dissipation layer, the thin film solar cells convert the light passing through the protection layer into electrical energy, the heat dissipation layer dissipates the heat generated by the thin film solar cells.

2. The apparatus of claim 1, wherein the protection layer is made of high strength and lightweight material.

3. The apparatus of claim 2, wherein the material of the protection layer is Polycarbonate.

4. The apparatus of claim 3, wherein each of the thin film solar cells comprises a substrate, an n-type semiconductor layer and a p-type semiconductor layer formed above the substrate, an anode formed on the p-type semiconductor, and a cathode formed on the n-type semiconductor.

5. The apparatus of claim 4, wherein the substrate is made of flexible material.

6. The apparatus of claim 4, wherein the n-type semiconductor layer and the p-type semiconductor layer are made of amorphous silicon.

7. The apparatus of claim 1, wherein the heat dissipation layer is made of lightweight material with high thermal conductivity.

8. The apparatus of claim 7, wherein the material of the heat dissipation layer is selected from a group consisting of metal alloy and graphite.

9. The apparatus of claim 1, wherein each of the thin film solar cells comprises an n-type semiconductor and a p-type semiconductor, the n-type semiconductor and the p-type semiconductor are directly formed on the heat dissipation layer.

10. An electronic device, comprising:
an enclosure;
a number of thin film solar cells in the enclosure; and
a power module connected to the thin film solar cells, wherein the thin film solar cells convert the light impinging on the thin film solar cells into electrical energy, and provide the electrical energy to components of the electronic device via the power module.

11. The electronic device of claim 10, wherein the enclosure comprises a protection layer and a heat dissipation layer, the thin film solar cells are formed between the protection layer and the heat dissipation layer.

12. The electronic device of claim 11, wherein the protection layer is made of Polycarbonate.

13. The electronic device of claim 11, wherein the material of the heat dissipation layer is selected from a group consisting of metal alloy and graphite.

14. The electronic device of claim 10, wherein each of the thin film solar cells comprises a substrate, an n-type semiconductor layer and a p-type semiconductor layer formed above the substrate, an anode formed on the p-type semiconductor, and a cathode formed on the n-type semiconductor.

15. The electronic device of claim 14, wherein the power module connects with both the anode and the cathode.

16. The electronic device of claim 14, wherein the substrate is made of flexible material.

17. The electronic device of claim 14, wherein the n-type semiconductor layer and the p-type semiconductor layer are made of amorphous silicon.

18. The electronic device of claim 10, wherein each of the thin film solar cells comprises an n-type semiconductor and a p-type semiconductor, the n-type semiconductor and the p-type semiconductor are directly formed on the heat dissipation layer.

19. The electronic device of claim 10, wherein the electronic device is notebook computer comprising a display enclosure and a keyboard enclosure, the thin film solar cells are form on both the display enclosure and the keyboard enclosure.
